(19) United States
(12) Patent Application Publication
(10) Pub. No.: US 2007/0249157 A1
(43) Pub. Date: Oct. 25, 2007

(54) Semiconductor device and method for manufacturing same

(75) Inventor: Yoshihisa Matsubara, Ibaraki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/785,820

(22) Filed: Apr. 20, 2007

(30) Foreign Application Priority Data
Apr. 21, 2006 (JP) 2006-117467

(51) Int. Cl. H01L 21/4763; H01L 23/48

(52) U.S. Cl. 438/622; 257/774

(57) ABSTRACT

A semiconductor device includes an interconnect group (TEG region) composed of a plurality of interconnects, which elongate along a first direction in a substrate surface of the substrate, and are arranged with a minimum interconnect interval therebetween in the semiconductor device, and a third interconnect, which elongates along a second direction that is included in the substrate surface of the substrate, and is perpendicular to the first direction, and is capable of electrically coupling a first interconnect included in the interconnect group to a second interconnect included in the interconnect group. The interconnect group and the interconnect are formed in an interconnect layer provided on the substrate.

This application is based on Japanese patent application No. 2006-117467, the content of which is incorporated hereinto by reference.

### BACKGROUND

1. Technical Field

The present invention relates to a semiconductor device and a method for manufacturing thereof.

2. Related Art

A typical test pattern utilized for evaluating a process for a semiconductor device will be described. A general view of a layout of a test chip for a general process evaluation is shown in FIG. 6. Maximum values of a horizontal width d1 and a vertical width d2 in a dimension of a test chip are generally defined by employing a maximum field size d3 of a lithographic apparatus. An evaluation pattern is composed of an assembly of evaluation blocks, which are also called as sub chips 603. The sub chips 603 in the interior of the testing block have an uniform dimension. The reason thereof is that the uniform dimension leads to a fixed arrangement of measuring probes and a constant moving distances thereof in a program for measurement, thereby allowing a sharing of a program and a common use of measurement probes.

Subsequently, an outline of a pattern for evaluating an interconnect-related process will be described in reference to FIG. 7. The pattern for evaluating the interconnect process includes via chains, a pattern for evaluating electro migration (EM), a pattern for measuring a leakage or the like, which are mounted therein. Concerning the via chain, a pattern scaling is generally changed according to the length of the interconnect to be evaluated and the number of vias. A defect density can also be evaluated by utilizing different pattern scaling. An evaluation block required for such process evaluation is referred to as test element group (TEG) region 701, an electrode that a probe for electrical measurement lets come into contact is called electrode pad 702, and an interconnect that couples the TEG region 701 to the electrode pad 702 is referred to as a drawing interconnect 703.

FIG. 8 is a plan view, which includes a via chain pattern TEG region 801 and drawing interconnects 802, which electrically couples the region 801 is to the electrode pads. In the via chain pattern TEG region 801, M1 interconnects 803 and M2 interconnects 804 are alternately disposed, and these interconnects are mutually coupled by vias 805. Meanwhile, linewidth d3 of the M1 interconnect 803 and the M2 interconnect 804 are 70 nm, which is equivalent to a minimum linewidth in the semiconductor device. A linewidth d4 of an isolated interconnect section is wider than the above-described linewidth d3, and is about 0.17 μm.

Subsequently, a process for forming a general interconnect will be described. FIGS. 9A to 9E are cross-sectional views, illustrating the process. First of all, an interlayer insulating film 902 composed of silicon oxide film or the like is formed on a substrate 901 via a chemical vapor deposition (CVD) process or the like (FIG. 9A). Elements such as transistors (not shown) are formed in the substrate 901. Then, a resist 903 is formed on the interlayer insulating film 902, and the formed resist 903 is patterned via a photolithographic process. Further, a pattern of the resist is transferred to the interlayer insulating film 902 via a dry etch technology (FIG. 9B). This allows forming trenches 904 for interconnects in desired positions. Then, the remained resist 903 is removed (FIG. 9C).

Then, a conductor film 905 such as a copper (Cu) film, an aluminum (Al) film and the like is deposited on the entire surface of the interlayer insulating film 902 (FIG. 9D). Then, the conductor film 905 is polished via a chemical mechanical polishing (CMP) process until the interlayer insulating film 902 is exposed.

As a result, an interconnect 906 having a damascene structure is formed in a desired location of the interlayer insulating film 902 (FIG. 9E).

A structure of a coupling interconnect from a certain isolated block to an electric block in electrically dense blocks is not limited to a TEG drawing interconnect for evaluating the process, and a similar structure is employed for the product. Therefore, a typical conventional product thereof will be described as follows.

FIG. 10 is a plan view, showing an outline of a general logic product. A conventional configuration in a general CPU logic circuit will be described in reference to FIG. 10. This product has four macro-functions, namely an input-output (I/O) block 1001, a random access memory (RAM) block 1002, a logic block 1003 and a phase locked loop (PLL) block 1004.

The I/O block 1001 is an area composed of only interconnects having the linewidth of not smaller than 1 μm. In such area, there is basically no need for a narrower interconnect. Further, this area serves as determining a limitation on an allowable high-current, and maximum values of the linewidth and the via dimension are determined by such area. An interconnect that mutually couples the circuit blocks in the I/O block is composed of two interconnects, namely an interconnect that is coupled to a pad electrode (input interconnect) and an interconnect that is coupled to an internal circuit (output interconnect).

The RAM block 1002 generally includes a memory device of around one megabyte. A priority is given to a miniaturization for the interconnects in such area over an operating speed. Therefore, this area is an area that best requires employing narrower interconnects. Relatively smaller number of wider interconnects are included in this area, and power supply interconnects and ground interconnects are alternately disposed with a pitch of a memory cell size.

The logic block 1003 is a cell, in which higher drive capacity is required, and is also a block, in which power supply interconnects are enhanced. A configuration of this area is basically similar to a configuration of a standard cell of a gate array. The configuration of this area related to the interconnects generally includes enhanced power supply interconnects as compared with that of the RAM, though it is similar to that of RAM. A plurality of couplings between macro circuits are generally included, unlikely in the case of the PLL.

Since stable operations of the power supply, the ground element and the capacitor element are prioritized in the PLL block 1004, the PLL block 1004 generally requires second widest linewidth, second only to the I/O region, though the interconnect density therein is lower. The PLL serves as amplifying a signal input from an external transmitter (amplifying a signal to, for example, in 4 times or 5 times of the original), so as to compose clock trees in respective macros.

A block coupling structure of two macro circuits in a logic unit will be described in reference to FIG. 11. In FIG. 11, a region between two macro circuits of a first logic region 1101 and a second logic region 1102 is a region 1103. Power supply meshes 1104 and ground meshes 1105 are disposed in the macro. Connections and signal interconnects 1106 serving as circuit structure factors are disposed between the power supply meshes 1104 and the ground meshes 1105 in the macro. Further, signal interconnects for mutually coupling these macros are drawn.

Details of the structure in the macro will be described in reference to FIG. 12. FIG. 12 shows a logic region 1201 and a region 1202 between macro circuits. Power supply meshes 1204 and ground meshes 1205 are disposed in the macro. Connections and signal interconnects 1206 serving as circuit structure factors are disposed between the power supply meshes 1204 and the ground meshes 1205 in the macro. A width d5 of the signal interconnect 1206 of a portion having no adjacent interconnect is generally wider than widths of other portions thereof. A linewidth of an isolated section 1203 in the macro coupling interconnect is selected to be wider than the above-described linewidth d5.

In addition to above, typical prior art documents related to the present invention includes Japanese Patent Laid-Open No. 2001-85614. A semiconductor device having an interconnect and via plugs coupled to an end portion of the interconnect is disclosed in Japanese Patent Laid-Open No. 2001-85614. In such semiconductor device, a coverage interconnect is coupled to the above-described end portion of the interconnect, for the purpose of preventing a poor contact between the interconnect and the via plug.

However, in the conventional technology, wider linewidth of the isolated section in the interconnect should have been selected. The reason is described in reference to a graph of FIG. 13. In FIG. 13, a case of dense-arranged interconnects having a linewidth of 70 nm (mark M1) is compared with a case of isolated interconnects having a target linewidth of 70 nm (mark M2). Having ±5 nm of a tolerance over a designed value of 70 nm (range shown by arrows A1 in the graph), a depth-of-focus (DOF) allowance of 0.2 μm is present for the dense-arranged pattern of 70 nm. On the other hand, a DOF allowance of lower than 0.2 μm can only be ensured in the case of the isolated interconnects of 70 nm. Since sufficient illumination contrast can not be ensured in the patterning of the isolated section in the interconnects as described above, a sensitivity for focusing is reduced.

Therefore, in order to provide substantially equal process windows for both of the dense-arranged interconnects and the isolated interconnects, it is required to design the linewidth of the isolated interconnect to be more wider than that of the dense-arranged interconnect. For example, an isolated interconnect is designed to have a linewidth of 90 nm, while the dense-arranged interconnect has a linewidth of 70 nm. In FIG. 13, marks M3 corresponds to the isolated interconnect of 90 nm.

In reference to, for example, FIG. 12 as described above, a portion of the signal interconnect 1206 sandwiched by the thick power supply mesh 1204 and the ground mesh 1205, or in other words a portion thereof having no adjacent interconnect, is isolated. Such isolated section extends across a boundary between a macro circuit (logic region 1201) and a region 1202 between macro circuits. Thus, it is required to select an increased design linewidth of the isolated section for the above described reason.

Such problem related to the isolated interconnect may also lead to a problem related to a difference in performances of devices. Illumination condition-dependency in the lithographic process for the interconnects is shown in FIG. 14. Cases indicated by marks M1 and arrow A1 in FIG. 14 is similar to that appeared in FIG. 13. Further, marks M4 and marks M5 represent lithographic processes for isolated interconnects having a linewidth of 70 nm, utilizing annular illumination and dipole illumination, respectively. As understood by the graph, different illumination conditions provide different DOF. Thus, when a plurality of lithographic apparatuses are employed for a mass production of a certain semiconductor device, a variation in the performances of the apparatuses causes a requirement for selecting different designed value by apparatuses. In the case, different masks should also be prepared by apparatuses.

### SUMMARY OF THE INVENTION

According to the present invention, there is provided a semiconductor device having an interconnect layer provided on a substrate, comprising: an interconnect group composed of a plurality of interconnects, the interconnects being provided in the interconnect layer, elongating along a first direction in a substrate surface of the substrate, and being arranged with a minimum interconnect interval therebetween in the semiconductor device; and a third interconnect, being provided in the interconnect layer and elongating along a second direction included in the substrate surface of the substrate, the second direction being perpendicular to the first direction, and the third interconnect being capable of electrically coupling a first interconnect included in the interconnect group to a second interconnect included in the interconnect group, wherein the first, the second and the third interconnects are provided in the same layer in the interconnect layer, and the third interconnect is disposed in an area except an end portion of the interconnect group.

In such semiconductor device, the electrical coupling between the first interconnect and the second interconnect is provided by the third interconnect that extends along a direction, which is perpendicular to directions to elongating directions of the first and the second interconnects. In addition to above, the third interconnect is disposed in an area except an end portion of the interconnect group that includes the first and the second interconnects. In other words, the third interconnect is not located in the above-described end portion. This configuration allows preventing a creation of an isolated interconnect.

According to the present invention, the semiconductor device, which is capable of preventing a creation of an isolated interconnect, and the method for manufacturing thereof are presented.

### BRIEF DESCRIPTION OF THE DRAWINGS

The above and other objects, advantages and features of the present invention will be more apparent from the following description taken in conjunction with the accompanying drawings, in which:

FIG. 1 is a plan view, showing a first embodiment of a semiconductor device according to the present invention;

FIG. 2 is a graph, useful in describing an advantageous effect of the embodiment;

FIG. 3 is a plan view, showing a second embodiment of a semiconductor device according to the present invention;

FIGS. 4A and 4B show results of aerial image simulations in the second embodiment;

FIG. 5 is a plan view, useful in describing a configuration of a signal line within a logic circuit according to the present invention;

FIG. 6 is a plan view, showing a layout of a general test chip for evaluating a process;

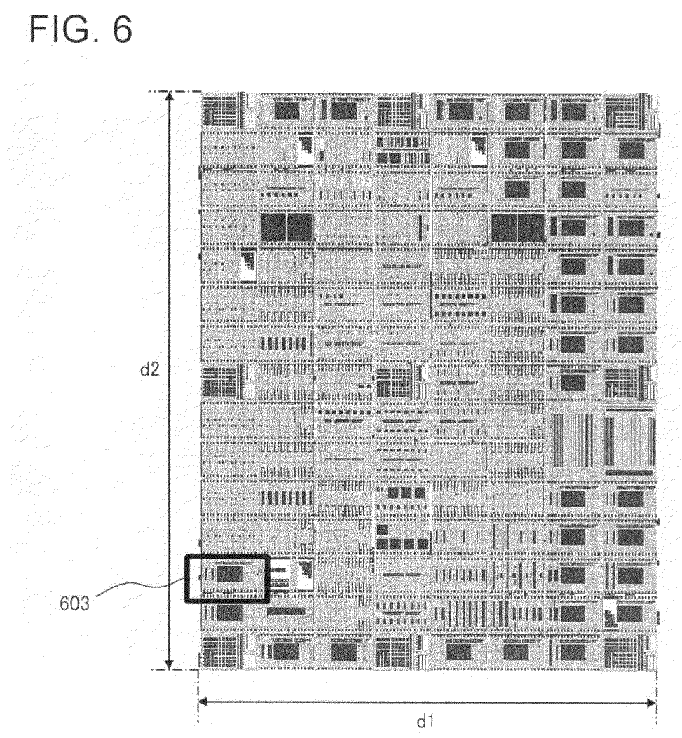

FIG. 7 is a plan view, useful in describing an outline of a pattern for evaluating an interconnect process;

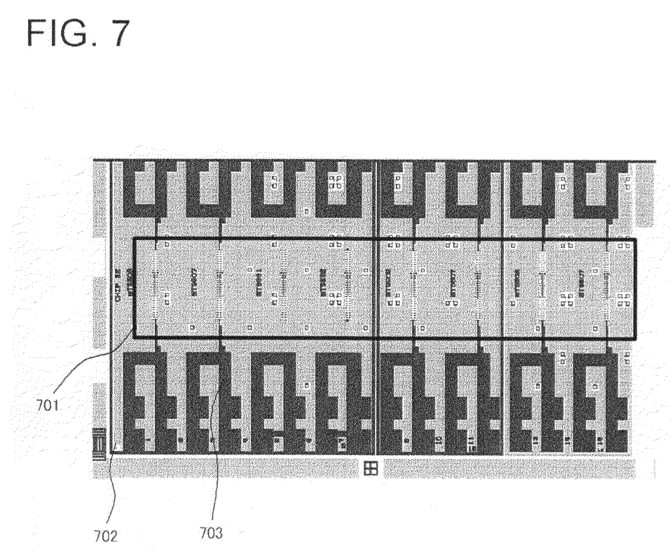

FIG. 8 is a plan view, which includes a via chain pattern TEG region and a drawing interconnect that electrically couples such TEG region to an electrode pad;

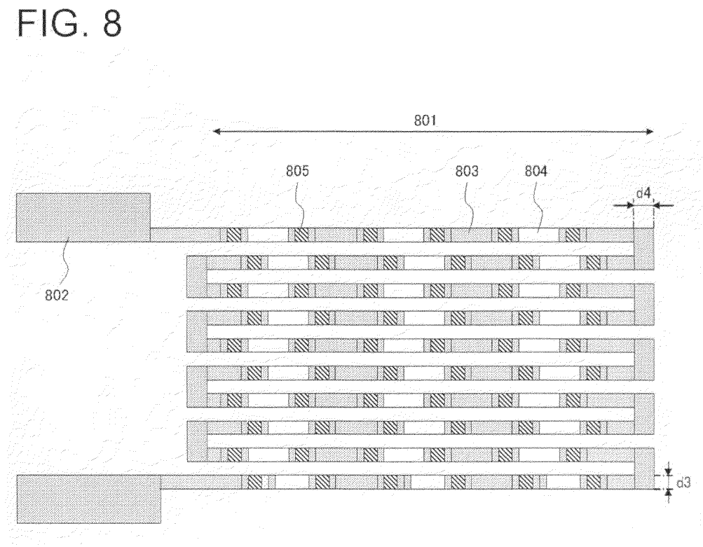

FIGS. 9A to 9E are cross-sectional views, useful in describing a general process for forming an interconnect;

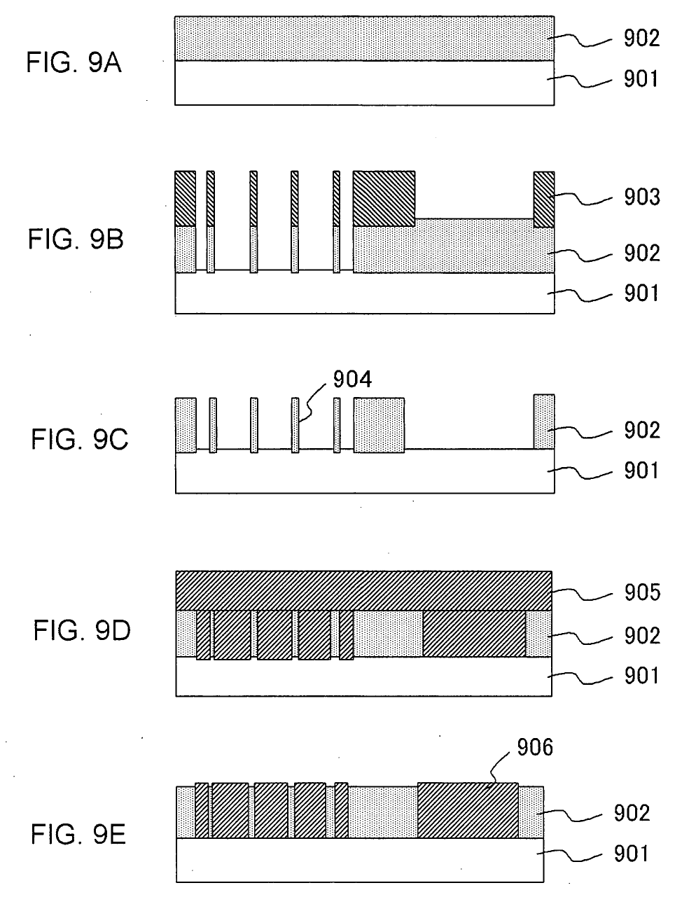

FIG. 10 is a plan view, showing an outline of a general logic product;

FIG. 11 is a plan view, useful in describing a block structure of two macro circuits in a logic unit of a general interconnect-arranging structure;

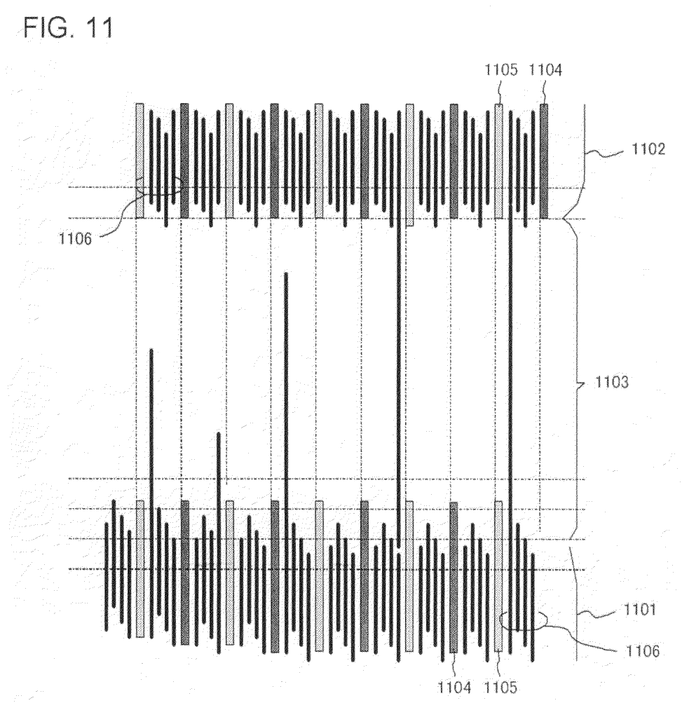

FIG. 12 is a plan view, useful in describing details of a structure in the macro;

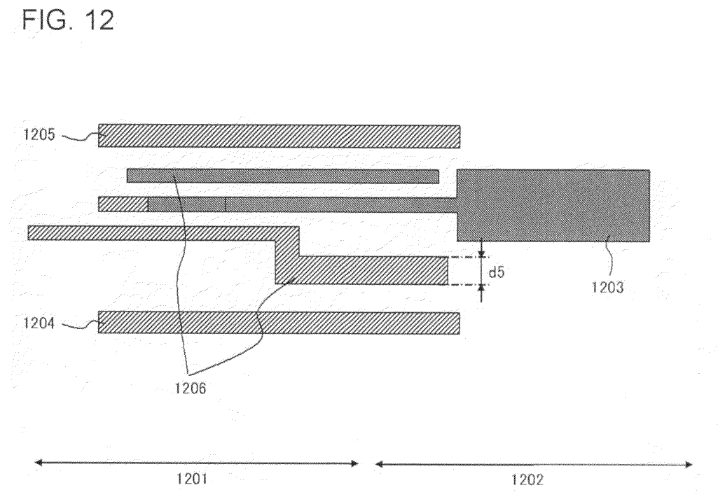

FIG. 13 is graph, showing an interconnect design width-dependency of a focus allowance; and

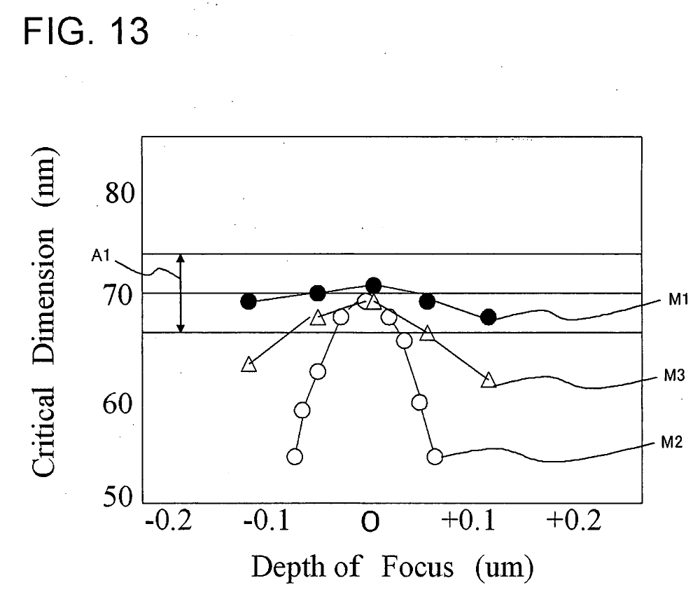

FIG. 14 is a graph, showing an illumination condition-dependency of a focus allowance.

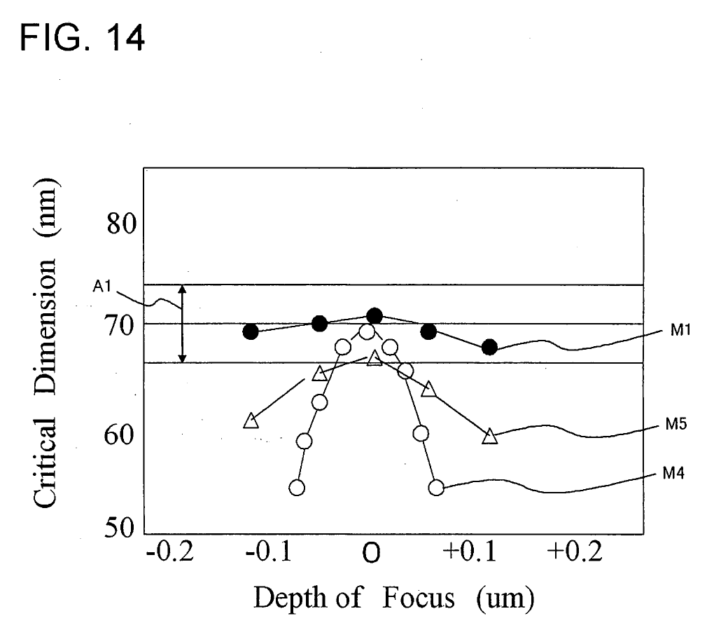

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations of semiconductor devices the method for manufacturing thereof according to the present invention will be described in reference to the annexed figures.

In all figures, identical numeral is assigned to an element commonly appeared in both of the description of the present invention the description of the related art, and the detailed description thereof will not be repeated.

### First Embodiment

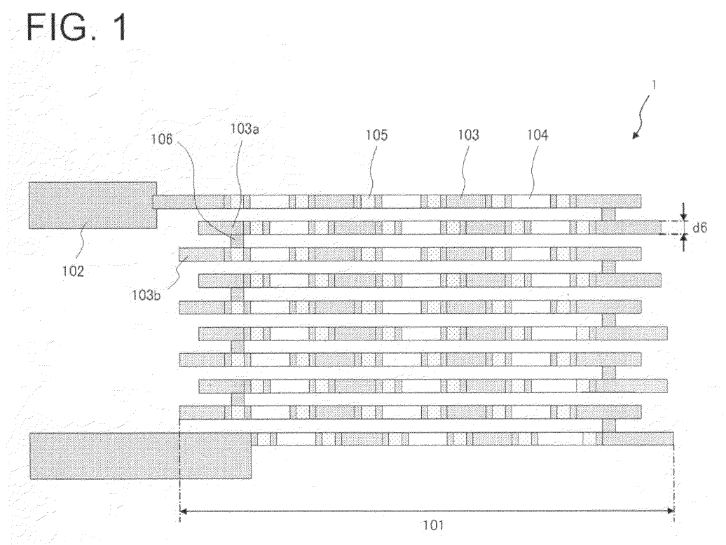

FIG. 1 is a plan view, showing a first exemplary implementation of a semiconductor device according to the present invention. A semiconductor device 1 includes an interconnect group (TEG region 101) composed of a plurality of interconnects, which elongate along a first direction (transverse direction in the diagram) in a substrate surface of the substrate, and are arranged with a minimum interconnect interval therebetween in the semiconductor device 1, and a third interconnect 106, which elongates along a second direction (longitudinal direction in the diagram) that is included in the substrate surface of said substrate, and is perpendicular to the first direction, and is capable of electrically coupling an interconnect 103a (first interconnect) included in the interconnect group to an interconnect 103b (second interconnect) included in the interconnect group.

The interconnect group and the interconnect 106 are formed in an interconnect layer provided on the substrate. In particular, the interconnect 103a, the interconnect 103b and the interconnect 106 are provided in the same layer in the above-described interconnect layer. As shown in FIG. 1, the interconnect 106 is disposed in an area except an end portion of the interconnect group. Meanwhile, the substrate and the interconnect layer are not shown in the diagram. Further, the substrate may be a semiconductor substrate, or may be a substrate other than a semiconductor substrate.

Both of the interconnect 103a and the interconnect 103b are portions of the M1 interconnect 103.

Further, linewidth d6 of the interconnect 103a and the interconnect 103b are equivalent to a minimum linewidth in the semiconductor device 1 (e.g., 70 mm). It is preferable that the minimum linewidth is equal to or smaller than 0.1 μm. M2 interconnects 104 are coupled to M1 interconnect 103 through vias 105. In the present embodiment, a linewidth of the M2 interconnect 104 is also equivalent to the above-described minimum linewidth.

The semiconductor device 1 is provided with a TEG region 101 for evaluating the via chain and drawing interconnects 102 for electrically coupling to the TEG region 101 to electrode pads. In the TEG region 101, the M1 interconnects 103 and the M2 interconnects 104 are alternately disposed, and these interconnects are mutually coupled through the vias 105.

As described above, in the present embodiment, an electrical coupling between the interconnect 103a and the interconnect 103b is created through the interconnect 106 in the central section (portion except end portion) of the interconnect group. This prevents a problem in the process optimization from causing in relation to a setback of a resist along x direction (transverse direction in the diagram). Further, the interconnect 106 is disposed between the interconnects that are arranged with a minimum interconnect interval therebetween along y direction (longitudinal direction in the diagram). Thus, a creation of an isolated interconnect is avoided. Therefore, formation processes for all of the interconnect 103a, the interconnect 103b and the interconnect 106 can be also conducted in the same process for forming the dense-arranged pattern.

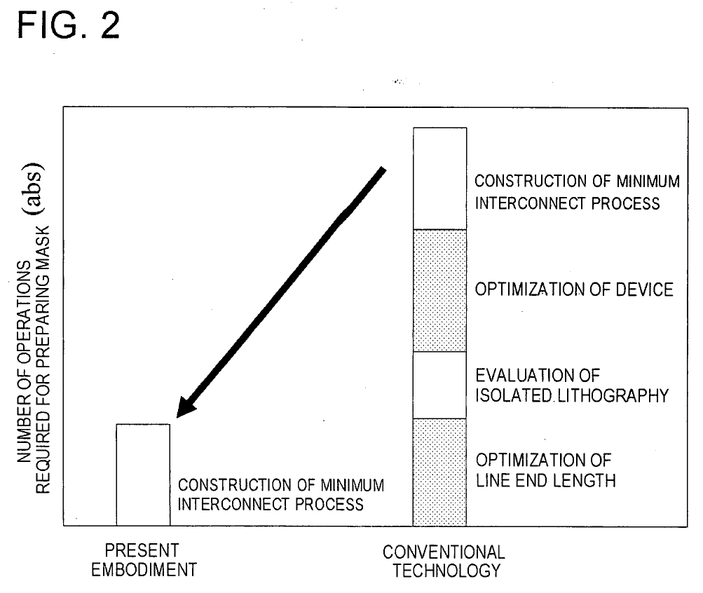

FIG. 2 is a bar graph, showing number of operations required for correcting an end portion of the interconnect group. In the conventional technology, four operations composed of an optimization of a line end length, an evaluation of an isolated lithography, an optimization of a device and a construction of a minimum interconnect process, are required. On the other hand, in the present embodiment, an optimization of a line end length, an evaluation of an isolated lithography and an optimization of a device are not required among these four operations. As described above, an interconnect-arranging structure of higher process sensitivity in terms of a circuit design, or in other words a structure including an isolated interconnect is inhibited, so that a design with higher process versatility and a reduced turn around time (TAT) can be advantageously achieved.

In addition to above, the method for manufacturing the semiconductor device 1 includes patterning the interconnect 103a, the interconnect 103b and the interconnect 106 via a photolithographic process utilizing a dipole illumination, and in such patterning operation, the photolithographic process is preferably conducted while a pole axis direction of the dipole illumination light is aligned to be substantially perpendicular to the above-described first direction. The pole axis direction of the dipole illumination light may also be rephrased into a direction of an arrangement of an effective light source distribution of the dipole illumination. Having such configuration, an axis of the dipole illumination can be selected to be along a direction that is parallel to a line joining two strength peaks of the dipole illumination light, so that an improved resolution of intervals that is parallel to such axis or of interconnects extending in a direction that is perpendicular to such axis can be achieved.

### Second Embodiment

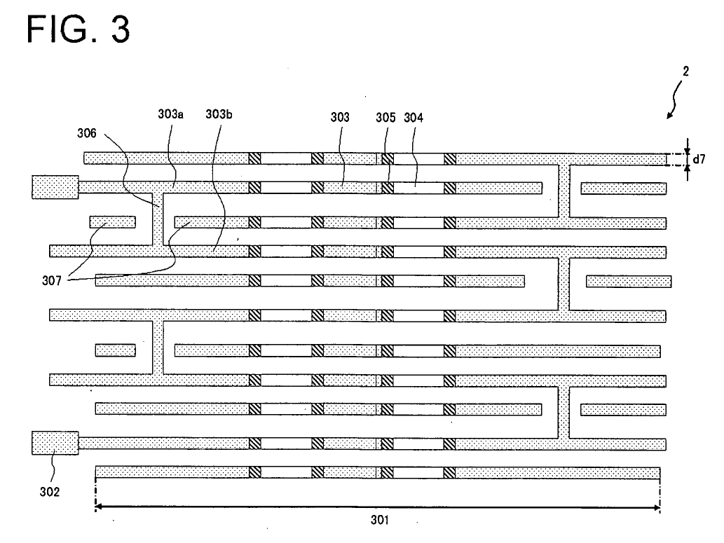

FIG. 3 is a plan view, showing a second exemplary implementation of a semiconductor device according to the present invention. A semiconductor device 2 includes an interconnect group (TEG region 301) composed of a plurality of interconnects, which elongate along a first direction (transverse direction in the diagram) in a substrate surface of the substrate, and are arranged with a minimum interconnect interval therebetween in the semiconductor device 2, and a third interconnect 306, which elongates along a second direction (longitudinal direction in the diagram) that is included in the substrate surface of said substrate, and is perpendicular to the first direction, and is capable of electrically coupling an interconnect 303a (first interconnect) included in the interconnect group to an interconnect 303b (second interconnect) included in the interconnect group.

The interconnect group and the interconnect 306 are formed in an interconnect layer provided on the substrate. In particular, the interconnect 303a, the interconnect 303b and the interconnect 306 are provided in the same layer in the above-described interconnect layer. Further, as shown in FIG. 3, the interconnect 306 is disposed in an area except an end portion of the interconnect group. Meanwhile, the substrate and the interconnect layer are not shown in the diagram.

Both of the interconnect 303a and the interconnect 303b are portions of the M1 interconnect 303. Further, linewidth d7 of the interconnect 303a and the interconnect 303b are equivalent to a minimum linewidth in the semiconductor device 2 (e.g., 70 mm). It is preferable that the minimum linewidth is equal to or less than 0.1 μm. M2 interconnects 304 are coupled to M1 interconnect 303 through vias 305. In the present embodiment, a linewidth of the M2 interconnect 304 is also equivalent to the above-described minimum linewidth.

The semiconductor device 2 is provided with a TEG region 301 for evaluating the via chain and drawing interconnects 302 for electrically coupling to the TEG region 301 to electrode pads. In the TEG region 301, the M1 interconnects 303 and the M2 interconnects 304 are alternately disposed, and these interconnects are mutually coupled through the vias 305.

Contrary to the situation in the first embodiment where the first interconnect (interconnect 103a) and the second interconnect (interconnect 103b) are two of mutually adjacent interconnects, the first interconnect (interconnect 303a) and the second interconnect (interconnect 303b) in the present embodiment are selected to be two of interconnects that are not mutually adjacent. The interconnect 306 is sandwiched between interconnects 307 in the above-described interconnect group, which are located between the interconnect 303a and the interconnect 303b. More specifically, the interconnect 307 is disposed on both sides of the interconnects 306.

The exemplary implementation of the via chain that requires the coupling between the interconnects, which are not mutually adjacent, has been illustrated in the present embodiment. As described above, the interconnect 306 having an interconnect direction perpendicular to the prioritized interconnect (interconnect 303a and interconnect 303b, or the like) is sandwiched between the interconnects in the interconnect group composed of a plurality of interconnects arranged with a minimum interconnect interval therebetween. This avoids a creation of an isolated interconnect, and an establishment of a simple optical proximity correction (OPC) can be achieved.

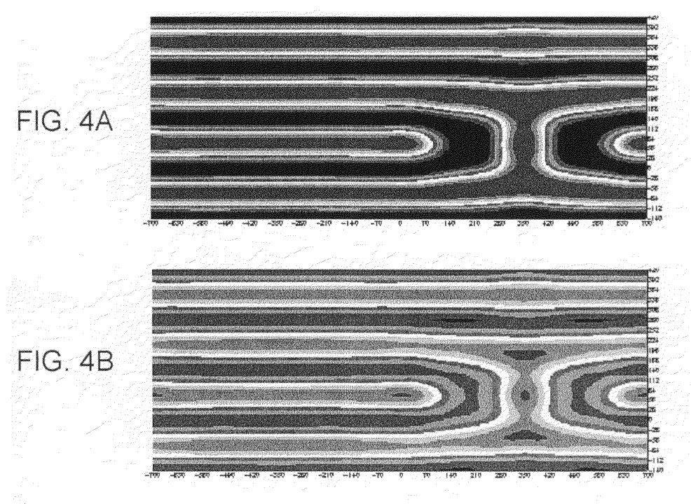

FIG. 4A and FIG. 4B show results of an aerial image simulation in the present embodiment. The former shows an image at an optimum focus location, and the latter shows an image in a location deviated from optimum focus location by 0.2 μm. It can be understood from the images that DOF of 0.2 μm or larger is assured.

In addition to above, the method for manufacturing the semiconductor device 2 includes patterning the interconnect 303a, the interconnect 303b and the interconnect 306 via a photolithographic process utilizing a dipole illumination, and in such patterning operation, the photolithographic process is preferably conducted while a pole axis direction of the dipole illumination light is aligned to be substantially perpendicular to the above-described first direction.

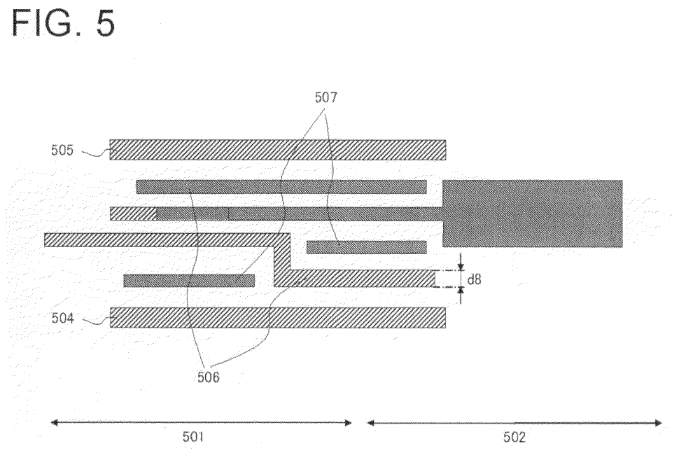

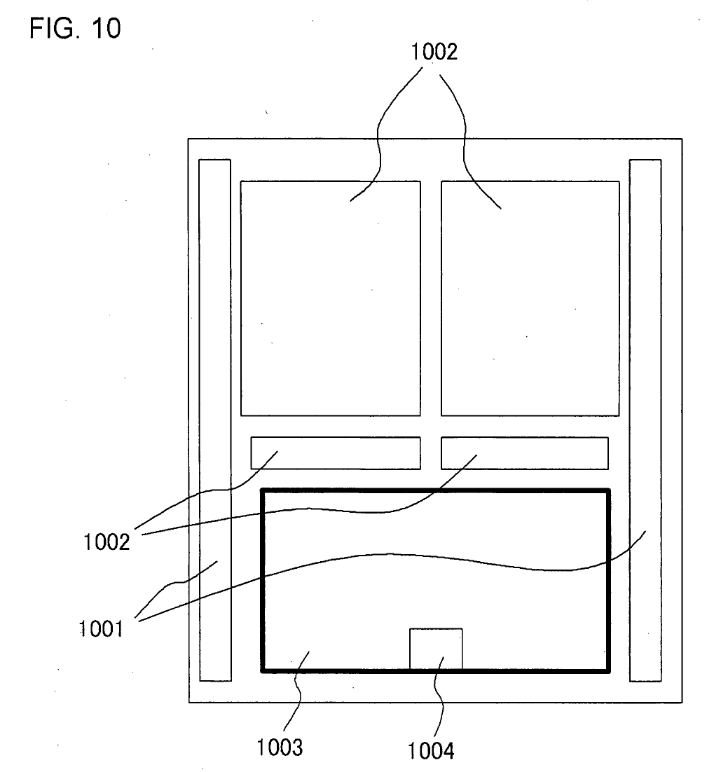

The present invention may also be applicable to, for example, a general logic circuit as shown in FIG. 10. Now, a configuration of a signal line within a logic circuit that the present invention is applied will be described in reference to FIG. 5. FIG. 5 shows a logic region 501 and a region 502 between macro circuits. Power supply meshes 504 and ground meshes 505 are disposed in the macro. Connections and signal interconnects 506 serving as circuit structure factors are disposed between the power supply meshes 504 and the ground meshes 505. By providing a pseudo interconnect 507 in parallel with the power supply mesh 504, a creation of a portion of an interconnect having no adjacent interconnect with a minimum interconnect interval, or in other words, a creation of an isolated interconnect portion, is prevented. As a result, the linewidth d8 of the signal interconnects 506 is unified in a minimum linewidth.

As described above, the present invention is not limited to an application for a TEG for process evaluation, and may be also applicable in general logic products. This allows a simple interconnect design in the products.

It is apparent that the present invention is not limited to the above embodiment, and may be modified and changed without departing from the scope and spirit of the invention.

What is claimed is:

1. A semiconductor device having an interconnect layer provided on a substrate, comprising:
a interconnect group composed of a plurality of interconnects, said interconnects being provided in said interconnect layer, elongating along a first direction in a substrate surface of said substrate, and being arranged with a minimum interconnect interval therebetween in the semiconductor device; and
a third interconnect, being provided in said interconnect layer and elongating along a second direction included in the substrate surface of said substrate, said second direction being perpendicular to said first direction, and said third interconnect being capable of electrically coupling a first interconnect included in said interconnect group to a second interconnect included in said interconnect group,
wherein said first, said second and said third interconnects are provided in the same layer in said interconnect layer, and
said third interconnect is disposed in an area except an end portion of said interconnect group.

2. The semiconductor device according to claim 1, wherein said first and said second interconnects are two interconnects in said interconnect group that are not adjacent each other, and said third interconnect is sandwiched between interconnects in said interconnect group, which are located between said first interconnect and said second interconnect.

3. The semiconductor device according to claim 1, wherein line widths of said first, said second and said third interconnects are equivalent to a minimum linewidth in the semiconductor device.

4. The semiconductor device according to claim 3, wherein said minimum linewidth of said first interconnect is equal to or less than 0.1 μm.

5. A method for manufacturing the semiconductor device as set forth in claim 1, comprising:
conducting a patterning for said first, said second and said third interconnects via a photolithographic process utilizing a dipole illumination,
wherein said conducting the patterning includes conducting said photolithographic process while a pole axis direction of said dipole illumination light is aligned to be substantially perpendicular to said first direction.
